(19) United States
(12) Patent Application Publication
(10) Pub. No.: US 2014/0307369 A1
(43) Pub. Date: Oct. 16, 2014

(54) MOBILE DEVICE AND METHOD OF CHANGING A SHAPE OF A MOBILE DEVICE

(71) Applicant: Samsung Display Co., Ltd., Yongin-City (KR)

(72) Inventors: Hyun-Jae Lee, Seoul (KR); Mu-Gyeom Kim, Yongin-City (KR)

(21) Appl. No.: 14/136,910

(22) Filed: Dec. 20, 2013

(30) Foreign Application Priority Data
Apr. 10, 2013 (KR) 10-2013-0039092

(51) Int. Cl. H05K 5/02

(52) U.S. Cl. CPC H05K 5/02
USPC 361/679.01

(57) ABSTRACT

A mobile device includes a rear cover, a front cover movably coupled to the rear cover, and at least one controlling unit disposed between the rear cover and the front cover, the controlling unit configured to control relative positions of the front cover and the rear cover based on an input value that is inputted by a user. A method of changing a shape of a mobile device includes executing a user application program; inputting an input value including at least one of an outer curvature of the mobile device and a changing-pattern of the outer curvature of the mobile device through the user application program; transmitting the input value to a driving controller; and controlling, by the driving controller, an controlling unit based on the input value.

### CLAIM OF PRIORITY

This application makes reference to, incorporates the same herein, and claims all benefits accruing under 35 U.S.C. §119 from an application for MOBILE DEVICE AND METHOD OF CHANGING A SHAPE OF A MOBILE DEVICE earlier filed in the Korean Intellectual Property Office on 10 Apr. 2013 and there duly assigned Ser. No. 10-2013-0039092.

### BACKGROUND OF THE INVENTION

1. Field of the Invention

The present invention relates to mobile device and method of changing a shape of a mobile device. More particularly, the present invention relates to a mobile device of which a shape is changed, a method of changing a shape of the mobile device.

2. Description of the Related Art

The use of a mobile device such as a laptop computer, a digital camera, a mobile phone, a smart phone, a smart pad, a personal digital assistant (PDA), a portable multimedia player (PMP), an MP3 player, a navigation device, a camcorder, a portable game console, etc has been increased due to developments of electronic and telecommunication industries.

However, a conventional mobile device has a fixed shape and cannot transform the shape adaptively according to usage conditions and/or situations, which results in the degradation of portability and usability.

### SUMMARY OF THE INVENTION

Example embodiments provide a mobile device having a changeable shape.

Example embodiments provide a method of changing a shape of the mobile device.

According to some example embodiments, a mobile device may include a rear cover, a front cover movably coupled to the rear cover, and at least one controlling unit disposed between the rear cover and the front cover, the controlling unit configured to control relative positions of the front cover and the rear cover based on an input value inputted by a user.

In example embodiments, the mobile device may further include a display panel disposed between the rear cover and the front cover, the display panel including a display region and a peripheral region bent to a back side of the display region, a supporting member disposed on the back side of the display panel and supporting the display panel, and an adhesive member interposed between the display panel and the supporting member, the adhesive member attaching the display panel and the supporting member to each other.

In example embodiments, the mobile device may further include a driving controller configured to control the controlling unit based on the input value.

In example embodiments, the driving controller may detect an event of the mobile device, and may control the controlling unit based on the event.

In example embodiments, the driving controller may include a database that stores a preset input signal corresponding to the event, may search the preset input signal from the database when the event is detected, and may control the controlling unit based on the searched preset input signal.

In example embodiments, the preset input signal may include at least one of an outer curvature of the mobile device corresponding to the event and a changing-pattern of the outer curvature of the mobile device corresponding to the event.

In example embodiments, the input value may include at least one of an outer curvature of the mobile device and a changing-pattern of the outer curvature of the mobile device that are inputted through a user application program.

In example embodiments, the controlling unit may be disposed along at least one of a longitudinal direction and a traverse direction of the rear cover.

In example embodiments, the controlling unit may include a controlling member and an operating member for operating the controlling member.

In example embodiments, the controlling member may include at least one of a micro actuator, an electro active polymer structure, and a moving structure.

In example embodiments, the moving structure may have at least one of a square shape, a square frame shape, a circular shape, an elliptical shape, and a polygonal shape.

According to some example embodiments, a method of changing a shape of a mobile device may include a step of executing a user application program, inputting an input value including at least one of an outer curvature of the mobile device and a changing-pattern of the outer curvature of the mobile device through the user application program, transmitting the input value to a driving controller, and controlling, by the driving controller, an controlling unit based on the input value.

In example embodiments, the method of changing a shape of a mobile device may further include a step of detecting an event of the mobile device and the driving controller controls the controlling unit based on the event.

In example embodiments, the driving controller may include a database that stores a preset input signal corresponding to the event, may search the preset input signal from the database when the event is detected, and may control the controlling unit based on the searched preset input signal.

In example embodiments, the preset input signal may include at least one of the outer curvature of the mobile device corresponding to the event and the changing-pattern of the outer curvature of the mobile device corresponding to the event.

In example embodiments, the driving controller may control the controlling unit such that the mobile device has the at least one of the outer curvature corresponding to the event and the changing-pattern of the outer curvature corresponding to the event included in the preset input signal.

In example embodiments, the driving controller may control the controlling unit such that the mobile device has the at least one of the outer curvature and the changing-pattern of the outer curvature included in the input value inputted through the user application program.

In example embodiments, the controlling unit may include a controlling member and an operating member for operating the controlling member and the controlling member includes at least one of a micro actuator, an electro active polymer structure, and a moving structure.

In example embodiments, the controlling unit may be disposed along at least one of a longitudinal direction and a traverse direction of the rear cover.

Therefore, a mobile device according to example embodiments may include a controlling unit that adjusts the arrangement of front and rear covers based on an input value, thereby changing a shape of the mobile device adaptively according to a user, a surrounding environment, an input condition, etc. Accordingly, portability and usability of the mobile device according to example embodiments may be improved.

### BRIEF DESCRIPTION OF THE DRAWINGS

Illustrative, non-limiting example embodiments will be more clearly understood from the following detailed description taken in conjunction with the accompanying drawings.

FIG. 1 is a cross-sectional view illustrating a mobile device in accordance with an embodiment of the present invention.

FIGS. 2A though 2C are cross-sectional views illustrating examples of operations of a controlling unit included in the mobile device of FIG. 1.

FIGS. 3A though 3C are cross-sectional views illustrating other examples of operations of a controlling unit included in the mobile device of FIG. 1.

FIGS. 4A though 4C are cross-sectional views illustrating still other examples of operations of a controlling unit included in the mobile device of FIG. 1.

FIG. 5 is a flow chart illustrating examples of a method of changing a shape of the mobile device of FIG. 1.

FIG. 6 is a flow chart illustrating other examples of a method of changing a shape of the mobile device of FIG. 1.

### DETAILED DESCRIPTION OF THE INVENTION

Various example embodiments will be described more fully hereinafter with reference to the accompanying drawings, in which example embodiments are shown. The present inventive concept may, however, be embodied in many different forms and should not be construed as being limited to the example embodiments set forth herein. Rather, these example embodiments are provided so that this disclosure will be thorough and complete, and will fully convey the scope of the present inventive concept to those skilled in the art. In the drawings, the sizes and relative sizes of layers and regions may be exaggerated for clarity. Like numerals refer to like elements throughout.

It will be understood that, although the terms first, second, third etc. may be used herein to describe various elements, these elements should not be limited by these terms. These terms are used to distinguish one element from another. Thus, a first element discussed below could be termed a second element without departing from the teachings of the present inventive concept. As used herein, the term “and/or” includes any and all combinations of one or more of the associated listed items.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Other words used to describe the relationship between elements should be interpreted in a like fashion (e.g., “between” versus “directly between,” “adjacent” versus “directly adjacent,” etc.).

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this inventive concept belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

Hereinafter, the present invention will be explained in detail with reference to the accompanying drawings.

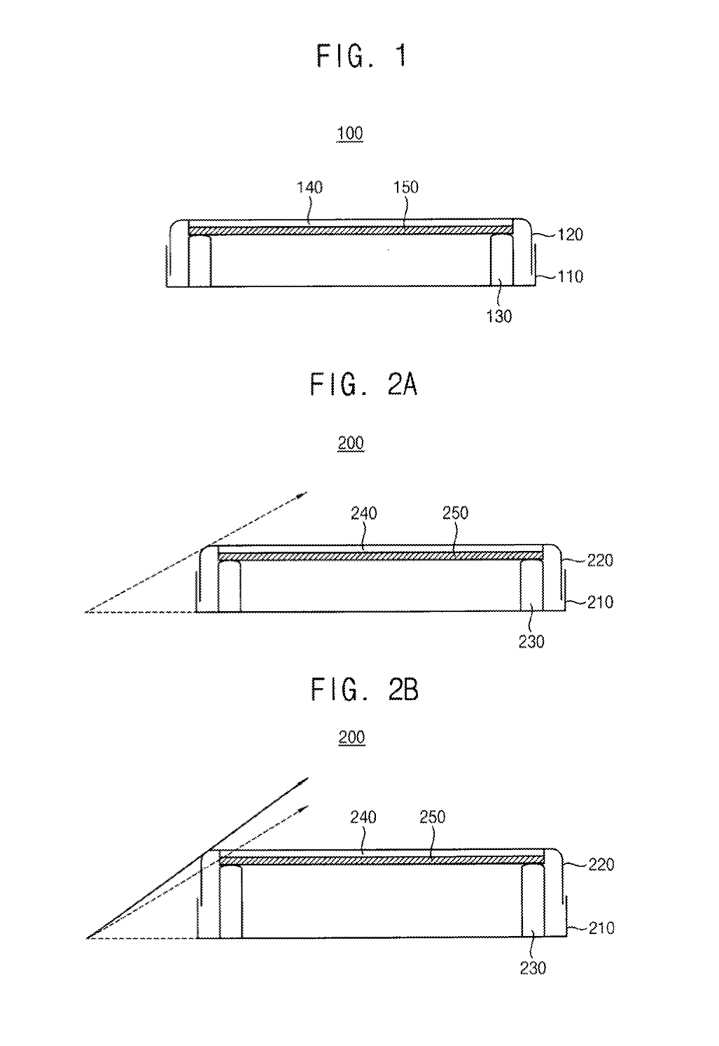

FIG. 1 is a cross-sectional view illustrating a mobile device according to an embodiment of the present invention.

Referring to FIG. 1, a mobile device 100 may include a rear cover 110, a front cover 120, and a controlling unit 130 having a controlling member 130a and an operating member 130b.

The mobile device 100 may further include a display panel 140 disposed between the rear cover 110 and the front cover 120. The mobile device 100 may further include a supporting member 150 disposed on a back side of the display panel 140. The supporting member 150 may support the display panel 140. Since the controlling unit 130 may contact with the supporting member 150, damage of the display panel 140 may be prevented. In this case, the display panel 140 and the supporting member 150 may be attached to each other by an adhesive member. The adhesive member may be interposed between the display panel 140 and the supporting member 150.

In example embodiments, the display panel 140 may correspond to a display panel of an organic light emitting display (OLED) device. However, the present inventive concept is not limited thereto. For example, the display panel 140 may correspond to a display panel of a liquid crystal display (LCD) device.

In example embodiments, the display panel 140, the supporting member 150 and the adhesive member may be disposed on the surface of the front cover 120.

For example, the rear cover 110 may include a material having a relatively high strength such as a stainless steel (STS), titanium (Ti), etc. Alternatively, the rear cover 110 may include a flexible material such as a transparent resin. Examples of the transparent resin for the rear cover 110 may include polyimide-based resin, acryl-based resin, polyacrylate-based resin, polycarbonate-based resin, polyether-based resin, sulfonic acid-containing resin, polyethyleneterephthalate-based resin, etc. These may be used alone or in a mixture thereof.

The front cover 120 may be movably coupled to the rear cover 110. For example, each of the rear cover 110 and the front cover 120 may include the substantially same material. Alternatively, each of the rear cover 110 and the front cover 120 may include different materials.

The controlling unit 130 may be positioned between the rear cover 110 and the front cover 120. In example embodiments, the controlling unit 130 may control relative positions of the front cover 120 and the rear cover 110 based on the input value inputted by a user. The relative positions of the front cover 120 and the rear cover 110 controlled by the controlling unit 130 will be described below in detail.

In example embodiments, the input value may be inputted through a user application program. Alternatively, the input value may be inputted through an environmental setting program, a bundle program (or, a bearer) embedded in an operating system (OS), etc.

The input value may include at least one of an outer curvature of the mobile device 100 and a changing-pattern of the outer curvature of the mobile device 100. The input value may be adjusted according to a user setting. For example, a user may set the outer curvature of the mobile device 100 and/or the changing-pattern of the outer curvature of the mobile device 100 by operating the user application program or the environment setting program. In addition, a shape of the mobile device 100 may be changed according to the set outer curvature of the mobile device 100 and/or the set changing-pattern of the outer curvature of the mobile device 100. Here, the user application program may be built in the mobile device 100. Alternatively, the user application program may be obtained through a wired network and a wireless network.

In example embodiments, the mobile device 100 may further include a driving controller that controls the controlling unit 130 based on the input value. Alternatively, the driving controller may detect an event of the mobile device 100 (e.g., a reception of a call, a reception of a text message, etc.), and may control the controlling unit 130 based on the event. To control the controlling unit 130 based on the event, the driving controller may include a database that stores a preset input signal corresponding to the event. In one example embodiment, the preset input signal may be prestored in the database when the mobile device 100 is manufactured. In another example embodiment, the preset input signal may be stored or updated in the database by a user setting. In still another example embodiment, the preset input signal may be adaptively stored or updated in the database by reflecting a user's habit to use the mobile device 100. The driving controller may search the preset input signal from the database when the event is detected, and may control the controlling unit 130 based on the searched preset input signal. The preset input signal may include at least one of an outer curvature of the mobile device 100 and a changing-pattern of the outer curvature of the mobile device 100.

In example embodiments, the controlling unit 130 may include the controlling member 130a and the operating member 130b for operating the controlling member 130a. For example, the controlling member 130a may include a member having elasticity. Examples of the controlling member 130a may include at least one of a micro actuator, an electro active polymer structure, and a moving structure. However, the present inventive concept is not limited thereto.

In example embodiments, the operating member 130b may operate the controlling member 130a. The operating member 130b may preferably include a micro motor. At least one operating member 130b may be provided to each controlling member 130a so that each controlling member 130a may be operated by the corresponding operating member 130b. However, the present inventive concept is not limited thereto. For example, one operating member may operate a plurality of the controlling members at the same time.

For example, the operating member 130b included in the controlling unit 130 may operate the controlling member 130a included in the controlling unit 130 to change a length of the controlling member 130a disposed between the front cover 120 and the rear cover 110. Accordingly, the controlling unit 130 may control the relative positions of the front cover 120 and the rear cover 110, which results in the change the shape of the mobile device 100.

Although the controlling member having a changeable length is described as the controlling member in FIG. 1, it should be understood that the controlling member may also be the controlling member having a changeable shape. For example, the operating member included in the controlling unit 130 may operate the controlling member included in the controlling unit 130 to change the shape of the controlling member disposed between the front cover 120 and the rear cover 110. Accordingly, the controlling unit 130 may change the shape of the mobile device 100.

In example embodiments, the controlling unit 130 may be disposed along at least one of a longitudinal direction and a traverse direction of the rear cover 110.

Therefore, the mobile device 100 according to example embodiments may include a controlling unit 130 that adjusts the arrangement (or the relative positions) of front and rear covers 110 and 120 based on an input value, thereby changing a shape of the mobile device 100 adaptively according to a user, a surrounding environment, an input condition, etc. Accordingly, portability and usability of the mobile device 100 according to example embodiments may be improved.

According to example embodiments, the mobile device 100 may be an electronic devices such as a mobile phone, a smart phone, a laptop computer, a tablet computer, a personal digital assistant (PDA), a portable multimedia player (PMP), a digital camera, a music player, a portable game console, a navigation device, etc.

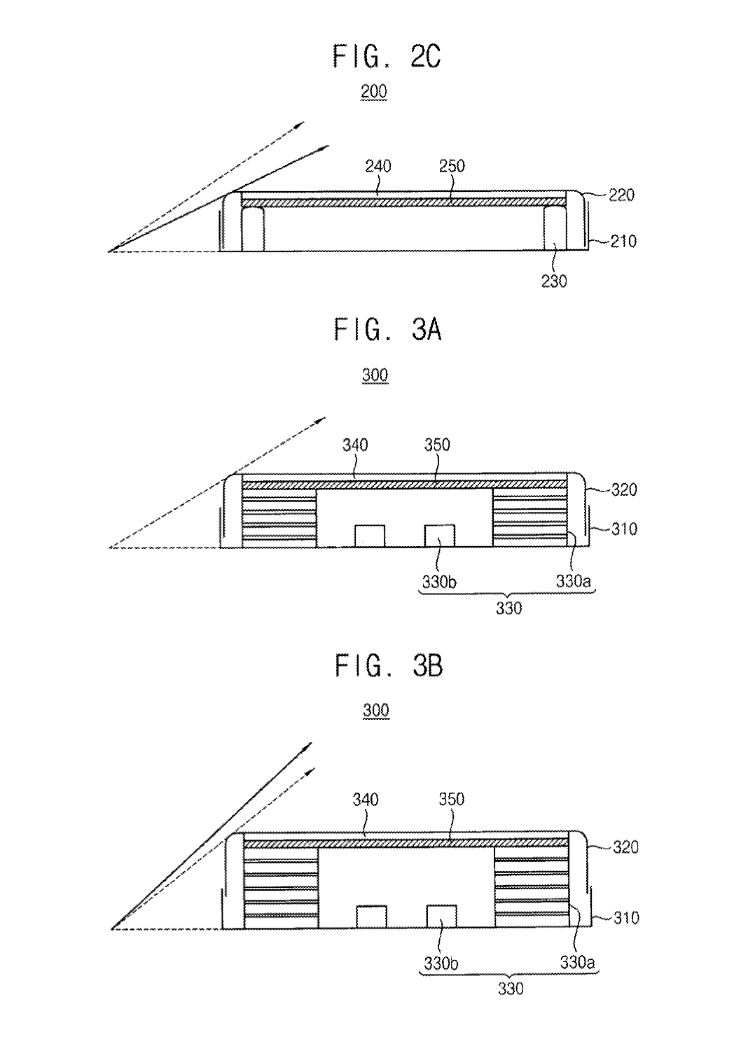

FIGS. 2A though 2C are cross-sectional views illustrating examples of operations of a controlling unit included in the mobile device of FIG. 1.

Referring to FIGS. 2A through 2C, a mobile device 200 may include a rear cover 210, a front cover 220, and at least one controlling unit 230.

At least one controlling unit 230 may control relative positions of the front cover 220 and the rear cover 210 based on an input value inputted by a user. The controlling unit 230 may have a micro actuator 230a and an operating member 230b. In example embodiments, the operating member 230b may be built in the micro actuator. The operating member may preferably include an electrical motor. For example, the input value inputted by the user may include at least one of an outer curvature of the mobile device 200 and a changing-pattern of the outer curvature of the mobile device 200.

Since the mobile device 200 of FIGS. 2A through 2C has a structure substantially the same as or substantially similar to mobile device 100 of FIG. 1 except for the controlling unit 230, duplicated descriptions will be omitted below.

Referring to FIG. 2A, the front cover 220 may be movably coupled to the rear cover 210.

The controlling unit 230 may include the micro actuator 230a and the operating member 230b. For example, at least one the controlling unit 230 may be positioned between the rear cover 210 and the front cover 220. In example embodiments, the controlling unit 230 may be controlled by a driving controller. The driving controller may control the controlling unit 230 based on the input value. In example embodiments, the input value may be inputted by a user through a user application program. Alternatively, the input value may be inputted through an environmental setting program, a bundle program (or, a bearer) embedded in an operating system (OS), etc. The input value may include at least one of an outer curvature of the mobile device 200 and a changing-pattern of the outer curvature of the mobile device 200. The input value may be adjusted according to a user setting. For example, a user may set the outer curvature of the mobile device 200 and/or the changing-pattern of the outer curvature of the mobile device 200 by operating the user application program or the environment setting program. In addition, a shape of the mobile device 200 may be changed according to the set outer curvature of the mobile device 200 and/or the set changing-pattern of the outer curvature of the mobile device 200. Here, the user application program may be built in the mobile device 200. Alternatively, the user application program may be obtained through a wired network and a wireless network.

In example embodiments, the driving controller may detect an event of the mobile device 200 (e.g., a reception of a call, a reception of a text message, etc.), and may control the controlling unit 230 based on the event as well as based on the input value inputted through the user application program. To control the controlling unit 230 based on the event, the driving controller may include a database that stores a preset input signal corresponding to the event. In one example embodiment, the preset input signal may be prestored in the database when the mobile device 200 is manufactured. In another example embodiment, the preset input signal may be stored or updated in the database by a user setting. In still another example embodiment, the preset input signal may be automatically and adaptively stored or updated in the database by reflecting a user's habit to use the mobile device 200. The driving controller may search the preset input signal from the database when the event is detected, and may control the controlling unit 230 based on the searched preset input signal. The preset input signal may include at least one of an outer curvature of the mobile device 200 and a changing-pattern of the outer curvature of the mobile device 200.

The micro actuator 230a included in the controlling unit 230 may be operated by the operating member 230b included in the controlling unit 230 to change a length of the micro actuator 230a disposed between the front cover 220 and the rear cover 210. Thus, the controlling unit 230 may control relative positions of the front cover 220 and the rear cover 210. In addition, an outer curvature of the mobile device 200 may be changed according to the changed length of the micro actuator.

For example, as illustrated in FIG. 2B, the driving controller may receive, as the input value, a value of an outer curvature of the mobile device 200 greater than a previous outer curvature of the mobile device 200 through the user application program. In this case, the driving controller may control the operating member 230b to increase a length of the micro actuator 230a. By the micro actuator 230a having the increased length, the outer curvature of the mobile device 200 may be increased to the received value of the outer curvature of the mobile device 200. Accordingly, the mobile device 200 may have an optimized structure according to usage conditions and/or situations of the user.

In other examples, as illustrated in FIG. 2C, the driving controller may receive, as the input value, a value of an outer curvature of the mobile device 200 smaller than a previous outer curvature of the mobile device 200 through the user application program. In this case, the driving controller may control the operating member 230b to decrease a length of the micro actuator 230a. By the micro actuator 230a having the decreased length, the outer curvature of the mobile device 200 may be decreased to the received value of the outer curvature of the mobile device 200. Accordingly, the mobile device 200 may have an optimized structure according to usage conditions and/or situations of the user.

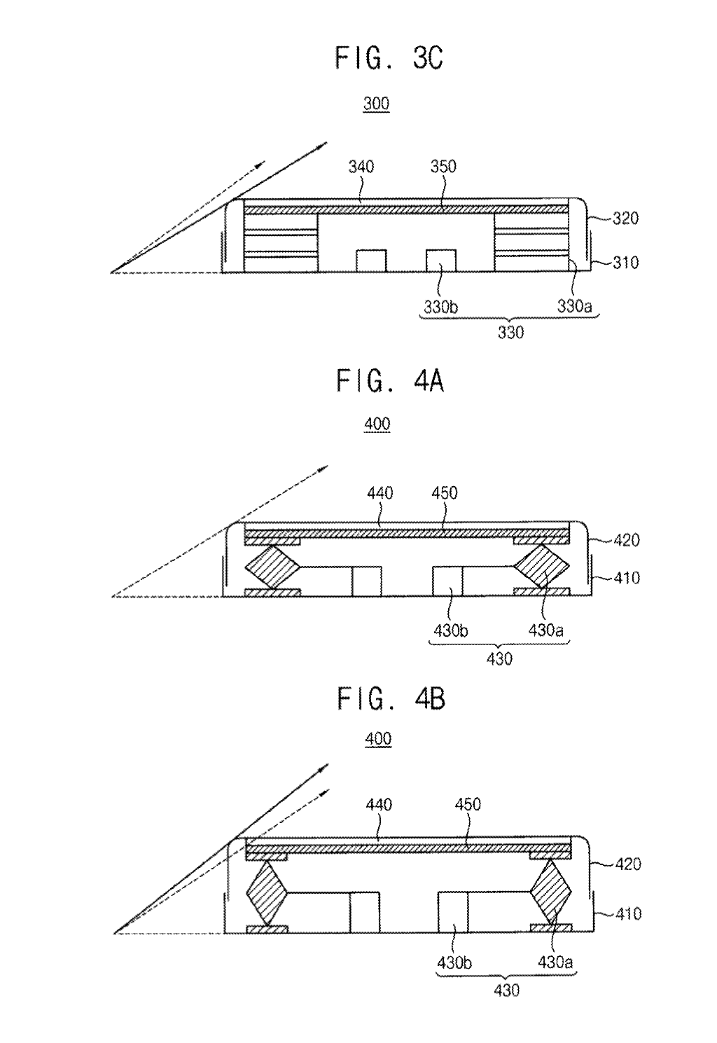

FIGS. 3A though 3C are cross-sectional views illustrating other examples of operations of a controlling unit included in the mobile device of FIG. 1.

Referring to FIGS. 3A through 3C, a mobile device 300 may include a rear cover 310, a front cover 320, and at least one controlling unit 330.

At least one controlling unit 330 may control relative positions of the front cover 320 and the rear cover 310 based on an input value inputted by a user. The controlling unit 330 may have a controlling member 330a which may include an electro active polymer structure 330a and an operating member 330b. In this case, the electro active polymer structure 330a may include a layered structure. For example, the electro active polymer structure 330a may include a single and/or multi layer which has an electro active polymer. In example embodiments, the operating member may preferably include an operating circuit that provides a voltage to the electro active polymer structure 330a. For example, the input value inputted by the user may include at least one of an outer curvature of the mobile device 300 and a changing-pattern of an outer curvature of the mobile device 300.

Since the mobile device 300 of FIGS. 3A through 3C has a structure substantially the same as or substantially similar to a mobile device 100 of FIG. 1 except for the controlling unit 330, duplicated descriptions will be omitted below.

Referring to FIG. 3A, the front cover 320 may be movably coupled to the rear cover 310.

The controlling unit 330 may include the electro active polymer structure 330a and the operating member 330b. For example, at least one the controlling unit 330 may be positioned between the rear cover 310 and the front cover 320. In example embodiments, the controlling unit 330 may be controlled by a driving controller. The driving controller may control the controlling unit 330 based on the input value. In example embodiments, the input value may be inputted through a user application program. Alternatively, the input value may be inputted through an environmental setting program, a bundle program (or, a bearer) embedded in an operating system (OS), etc.

The input value may include at least one of an outer curvature of the mobile device 300 and a changing-pattern of the outer curvature of the mobile device 300. The input value may be adjusted according to a user setting. For example, a user may set the outer curvature of the mobile device 300 and/or the changing-pattern of the outer curvature of the mobile device 300 by operating the user application program or the environment setting program. In addition, a shape of the mobile device 300 may be changed according to the set outer curvature of the mobile device 300 and/or the set changing-pattern of the outer curvature of the mobile device 300. Here, the user application program may be built in the mobile device 300. Alternatively, the application may be obtained through a wired network and a wireless network.

In example embodiments, the driving controller may detect an event of the mobile device 300 (e.g., a reception of a call, a reception of a text message, etc.), and may control the controlling unit 330 based on the event. To control the controlling unit 330 based on the event, the driving controller use a database that stores a preset input signal corresponding to the event. In one example embodiment, the preset input signal may be prestored in the database when the mobile device 300 is manufactured. In another example embodiment, the preset input signal may be stored or updated in the database by a user setting. In still another example embodiment, the preset input signal may be automatically and adaptively stored or updated in the database by reflecting a user's habit to use the mobile device 300. The driving controller may search the preset input signal from the database when the event is detected, and may control the controlling unit 330 based on the searched preset input signal. The preset input signal may include at least one of an outer curvature of the mobile device 300 and a changing-pattern of the outer curvature of the mobile device 300.

The operating member 330b included in the controlling unit 330 may operate the electro active polymer structure 330a included in the controlling unit 330 to change a volume of the electro active polymer structure 330a disposed between the front cover 320 and the rear cover 310. Thus, the controlling unit 330 may control relative positions of the front cover 320 and the rear cover 310. In addition, an outer curvature of the mobile device 300 may be changed according to the changed volume of the electro active polymer structure 330a.

For example, as illustrated in FIG. 3B, the driving controller may receive, as the input value, a value of an outer curvature of the mobile device 300 greater than a previous outer curvature of the mobile device through the user application program. In this case, the driving controller may control the operating member 330b to increase a volume of the electro active polymer structure 330a. By the electro active polymer structure 330a having the increased volume, the outer curvature of the mobile device 300 may be increased to the received value of the outer curvature of the mobile device 300. Accordingly, the mobile device 300 may have an optimized structure according to usage conditions and/or situations of the user.

In other examples, as illustrated in FIG. 3C, the driving controller may receive, as the input value, a value of an outer curvature of the mobile device 300 smaller than a previous outer curvature of the mobile device through the user application program. The driving controller may control the operating member 330b to decrease a volume of the electro active polymer structure 330a. By the electro active polymer structure 330a having the decreased volume, the outer curvature of the mobile device 300 may be decreased to the received value of the outer curvature of the mobile device 300. Accordingly, the mobile device 300 may have an optimized structure according to usage conditions and/or situations of the user.

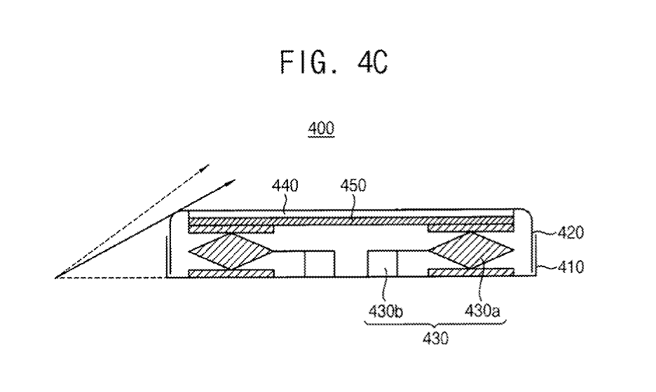

FIGS. 4A though 4C are cross-sectional views illustrating still other examples of operations of a controlling unit included in the mobile device of FIG. 1.

Referring to FIGS. 4A though 4C, a mobile device 400 may include a rear cover 410, a front cover 420, and at least one controlling unit 430.

At least one controlling unit 430 illustrated in FIGS. 4A through 4C may have a controlling member 430a including a moving structure and an operating member 430b. In example embodiments, the operating member 430b may preferably include a micro motor that operates moving structure 430a. For example, the input value inputted by the user may include at least one of an outer curvature of the mobile device 400 and a changing-pattern of an outer curvature of the mobile device 400.

Since the mobile device 400 of FIGS. 4A through 4C has a structure substantially the same as or substantially similar to mobile device 100 of FIG. 1 except for the controlling unit 430, duplicated descriptions will be omitted below.

Referring to FIG. 4A, the front cover 420 may be movably coupled to the rear cover 410.

The controlling unit 430 may include the moving structure 430a and an operating member 430b. For example, at least one the controlling unit 430 may be positioned between the rear cover 410 and the front cover 420. In example embodiments, the controlling unit 430 may be controlled by a driving controller. The driving controller may control the controlling unit 430 based on the input value. In example embodiments, the input value may be inputted through a user application program. Alternatively, the input value may be inputted through an environmental setting program, a bundle program (or, a bearer) embedded in an operating system (OS), etc.

The input value may include at least one of an outer curvature of the mobile device 400 and a changing-pattern of the outer curvature of the mobile device 400. The input value may be adjusted according to a user setting. For example, a user may set the outer curvature of the mobile device 400 and/or the changing-pattern of the outer curvature of the mobile device 400 by operating the user application program or the environment setting program. In addition, a shape of the mobile device 400 may be changed according to the set outer curvature of the mobile device 400 and/or the set changing-pattern of the outer curvature of the mobile device 400. Here, the user application program may be built in the mobile device 400. Alternatively, the user application program may be obtained through a wired network and a wireless network.

In example embodiments, the driving controller may detect an event of the mobile device 400 (e.g., a reception of a call, a reception of a text message, etc.), and may control the controlling unit 430 based on the event. To control the controlling unit 430 based on the event, the driving controller may include a database that stores a preset input signal corresponding to the event. In one example embodiment, the preset input signal may be prestored in the database when the mobile device 400 is manufactured. In another example embodiment, the preset input signal may be stored or updated in the database by a user setting. In still another example embodiment, the preset input signal may be adaptively stored or updated in the database by reflecting a user's habit to use the mobile device 400. The driving controller may search the preset input signal from the database when the event is detected, and may control the controlling unit 430 based on the searched preset input signal. The preset input signal may include at least one of an outer curvature of the mobile device 400 and a changing-pattern of the outer curvature of the mobile device 400. In example embodiments, an operating type of the moving structure 430a may be similar to an operating type of a jackey for an automobile. The operating member 430b included in the controlling unit 430 may operate the moving structure 430a included in the controlling unit 430 to change a length of the moving structure 430a disposed between the front cover 420 and the rear cover 410. Thus, the controlling unit 430 may control relative positions of the front cover 420 and the rear cover 410. In addition, an outer curvature of the mobile device 400 may be changed according to the changed length of the moving structure 430a.

For example, as illustrated in FIG. 4B, the driving controller may receive, as the input value, a value of an outer curvature of the mobile device 400 greater than a previous outer curvature of the mobile device, through the user application program. In this case, the driving controller may control the operating member 430b to increase a length of the moving structure 430a. By the moving structure 430a having the increased length, the outer curvature of the mobile device 400 may be increased to the received value of the outer curvature of the mobile device 400. Accordingly, the mobile device 400 may have an optimized structure according to usage conditions and/or situations of the user.

In other examples, as illustrated in FIG. 4C, the driving controller may receive, as the input value, a value of an outer curvature of the mobile device 400 smaller than a previous outer curvature of the mobile device, through the user application program. In this case, the driving controller may control the operating member 430b to decrease a length of the moving structure 430a. By the operating member 430b having the decreased length, the outer curvature of the mobile device 400 may be decreased to the received value of the outer curvature of the mobile device 400. Accordingly, the mobile device 400 may have an optimized structure according to usage conditions and/or situations of the user.

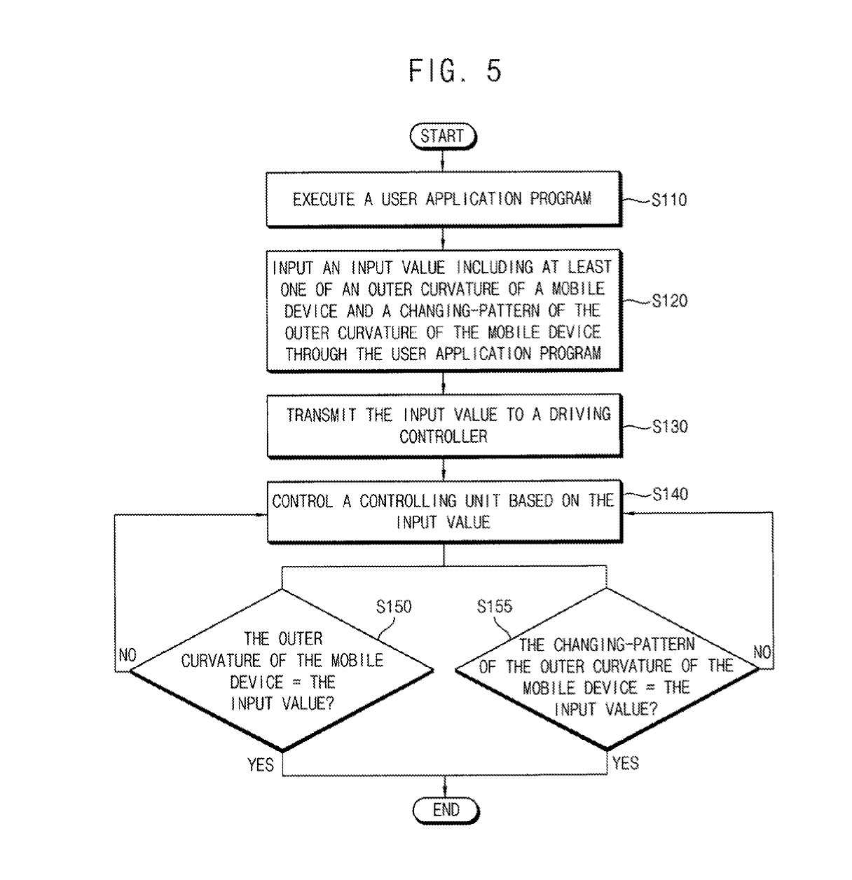

FIG. 5 is a flow chart illustrating examples of a method of changing a shape of the mobile device of FIG. 1.

Referring to FIGS. 1 and 5, a user application program in the mobile device 100 including the rear cover 110, the front cover 120 and at least one controlling unit 130 may be executed (Step S110).

Then, an input value including at least one of an outer curvature of the mobile device 100 and a changing-pattern of the outer curvature of the mobile device 100 may be inputted through the user application program (Step S120).

Specifically, the input value may be provided to the driving controller (Step S130).

Subsequently, the driving controller may control the controlling unit 130 based on the input value (Step S140).

In one example embodiment, a control of the controlling unit 130 may be stopped when the outer curvature of the mobile device 100 is matched to the input value (Step S150). That is, the driving controller may control the controlling unit 130 such that the mobile device 100 has the outer curvature indicated by the input value.

In another example embodiment, a control of the controlling unit 130 may be stopped when the changing-pattern of the outer curvature of the mobile device 100 is matched to the input value (Step S155). That is, the driving controller may control the controlling unit 130 such that the mobile device 100 has the changing-pattern of the outer curvature indicated by the input value.

In example embodiments, the mobile device 100 may include the controlling unit 130 that adjusts the arrangement (or relative positions) of front and rear covers 110 and 120 based on the input value, thereby changing a shape of the mobile device 100 adaptively according to a user, a surrounding environment, an input condition, etc. Accordingly, portability and usability of the mobile device 100 according to example embodiments may be improved.

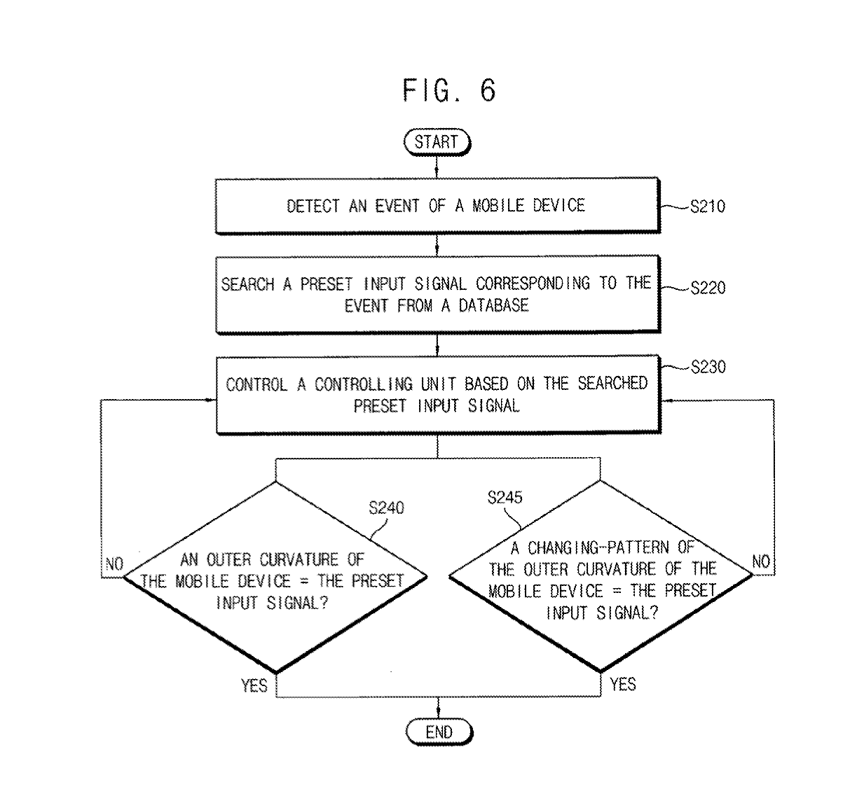

FIG. 6 is a flow chart illustrating other examples of a method of changing a shape of the mobile device of FIG. 1.

Referring to FIGS. 1 and 6, a driving controller may detect an event of the mobile device 100 (Step S210).

In example embodiments, the event may include a reception of a call, a reception of a text message, etc. A preset input signal corresponding to the event may be stored in a database. In one example embodiment, the preset input signal may be prestored in the database when the mobile device 100 is manufactured. In another example embodiment, the preset input signal may be stored or updated in the database by a user setting. In still another example embodiment, the preset input signal may be adaptively stored or updated in the database by reflecting a user's habit to use the mobile device 100.

The preset input signal corresponding to the event may be searched from the database (Step S220).

The driving controller may control the controlling unit 130 based on the searched preset input signal (Step S230).

In example embodiments, the preset input signal may include at least one of an outer curvature of the mobile device 100 and a changing-pattern of the outer curvature of the mobile device 100.

In one example embodiment, a control of the controlling unit 130 may be stopped when the outer curvature of the mobile device 100 is matched to the preset input value (Step S240). That is, the driving controller may control the controlling unit 130 such that the mobile device 100 has the outer curvature indicated by the preset input value.

In another example embodiment, a control of the controlling unit 130 may be stopped when the changing-pattern of the outer curvature of the mobile device 100 is matched to the preset input signal (Step S245). That is, the driving controller may control the controlling unit 130 such that the mobile device 100 has the changing-pattern of the outer curvature indicated by the preset input value.

According to example embodiments of the present invention, the mobile device 100 may include the controlling unit 130 that adjusts the arrangement (or relative positions) of front and rear covers 110 and 120 based on the input value, thereby changing a shape of the mobile device 100 adaptively according to a user, a surrounding environment, an input condition, etc. Accordingly, portability and usability of the mobile device 100 according to example embodiments may be improved.

Table 1 shows examples of the database that stores the preset input signal corresponding to the event of the mobile device.

TABLE 1

| | Reception | Reception | Reception | Reception | |
|---|---|---|---|---|---|
| | of A's | of B's | of A's | of B's | Sending |
| | call | call | message | message | a call |
| Outer | 3 | 4 | 2 | 3 | 1 |
| curvature | | | | | |
| Changing- | 2, 3, 2 | 2, 4, 2 | 1, 2, 1 | 1, 3, 1 | — |
| pattern | | | | | |
| of outer | | | | | |
| curvature | | | | | |

Referring to Table 1, the event of the mobile device may include a reception of a call, a reception of a message, a sending a call, etc. In this case, the preset input signal may include at least one of an outer curvature of the mobile device and a changing-pattern of the outer curvature of the mobile device.

For example, the driving controller may search the preset input signal from the database, and may change a value of the outer curvature of the mobile device to 3 based on the searched preset input signal when a driving controller receives an occurrence of an event (e.g., a reception of A's call).

For example, the driving controller may search the preset input signal from the database, and may change a value of the outer curvature of the mobile device to 4 based on the searched preset input signal when a driving controller receives an occurrence of an event (e.g., a reception of B's call).

According to example embodiments of the present invention, the mobile device may be any electronic devices such as a mobile phone, a smart phone, a laptop computer, a tablet computer, a personal digital assistant (PDA), a portable multimedia player (PMP), a digital camera, a music player, a portable game console, a navigation device, etc.

The foregoing is illustrative of example embodiments of the present invention and is not to be construed as limiting thereof. Although a few example embodiments have been described, those skilled in the art will readily appreciate that many modifications are possible in the example embodiments without materially departing from the novel teachings and advantages of the present inventive concept. Accordingly, all such modifications are intended to be included within the scope of the present inventive concept as defined in the claims. Therefore, it is to be understood that the foregoing is illustrative of various example embodiments and is not to be construed as limited to the specific example embodiments disclosed, and that modifications to the disclosed example embodiments, as well as other example embodiments, are intended to be included within the scope of the appended claims.

What is claimed is:

1. A mobile device comprising:
a rear cover;
a front cover movably coupled to the rear cover; and
at least one controlling unit disposed between the rear cover and the front cover, the controlling unit configured to control relative positions of the front cover and the rear cover based on an input value inputted by a user.

2. The mobile device of claim 1, further comprising:
a display panel disposed between the rear cover and the front cover, the display panel including a display region and a peripheral region bent to a back side of the display region;
a supporting member disposed on the back side of the display panel and supporting the display panel; and
an adhesive member interposed between the display panel and the supporting member, the adhesive member attaching the display panel and the supporting member to each other.

3. The mobile device of claim 2, further comprising:
a driving controller configured to control the controlling unit based on the input value.

4. The mobile device of claim 3, wherein the driving controller detects an event of the mobile device, and controls the controlling unit based on the event.

5. The mobile device of claim 4, wherein the driving controller includes a database that stores a preset input signal corresponding to the event, searches the preset input signal from the database when the event is detected, and controls the controlling unit based on the searched preset input signal.

6. The mobile device of claim 5, wherein the preset input signal includes at least one of an outer curvature of the mobile device corresponding to the event and a changing-pattern of the outer curvature of the mobile device corresponding to the event.

7. The mobile device of claim 1, wherein the input value includes at least one of an outer curvature of the mobile device and a changing-pattern of the outer curvature of the mobile device that are inputted through a user application program.

8. The mobile device of claim 1, wherein the controlling unit is disposed along at least one of a longitudinal direction and a traverse direction of the rear cover.

9. The mobile device of claim 1, wherein the controlling unit comprises:
a controlling member; and
an operating member for operating the controlling member.

10. The mobile device of claim 9, wherein the controlling member includes at least one of a micro actuator, an electro active polymer structure, and a moving structure.

11. The mobile device of claim 10, wherein the moving structure has at least one of a square shape, a square frame shape, a circular shape, an elliptical shape, and a polygonal shape.

12. A method of changing a shape of a mobile device comprising:
executing a user application program;
inputting an input value including at least one of an outer curvature of the mobile device and a changing-pattern of the outer curvature of the mobile device through the user application program;
transmitting the input value to a driving controller; and
controlling, by the driving controller, an controlling unit based on the input value.

13. The method of claim 12, further comprising:
detecting an event of the mobile device,
wherein the driving controller controls the controlling unit based on the event.

14. The method of claim 13, wherein the driving controller includes a database that stores a preset input signal corresponding to the event, searches the preset input signal from the database when the event is detected, and controls the controlling unit based on the searched preset input signal.

15. The method of claim 14, wherein the preset input signal includes at least one of the outer curvature corresponding to the event and the changing-pattern of the outer curvature corresponding to the event.

16. The method of claim 15, wherein the driving controller controls the controlling unit such that the mobile device has the at least one of the outer curvature corresponding to the event and the changing-pattern of the outer curvature corresponding to the event included in the preset input signal.

17. The method of claim 12, wherein the driving controller controls the controlling unit such that the mobile device has the at least one of the outer curvature and the changing-pattern of the outer curvature included in the input value inputted through the user application program.

18. The method of claim 12, wherein the controlling unit comprises:
a controlling member; and
an operating member for operating the controlling member, and
wherein the controlling member includes at least one of a micro actuator, an electro active polymer structure, and a moving structure.

19. The method of claim 12, wherein the controlling unit is disposed along at least one of a longitudinal direction and a traverse direction of the rear cover.
